(19) United States
(12) Patent Application Publication
(10) Pub. No.: US 2023/0103898 A1
(43) Pub. Date: Apr. 6, 2023

(54) BULK ACOUSTIC WAVE RESONATOR WITH REDUCED PERIMETER LEAKAGE

(71) Applicant: Skyworks Global Pte. Ltd., Singapore (SG)

(72) Inventors: Benjamin Paul Abbott, Irvine, CA (US); Mihir Shailesh Patel, Hopkinton, MA (US); Kwang Jae Shin, Yongin (KR)

(21) Appl. No.: 17/937,312

(22) Filed: Sep. 30, 2022

Related U.S. Application Data
(60) Provisional application No. 63/251,849, filed on Oct. 4, 2021.

(51) Int. Cl. H03H 3/04; H03H 9/02

(52) U.S. Cl. CPC H03H 3/04; H03H 9/02015; H03H 2003/0435

(57) ABSTRACT

A bulk acoustic wave resonator having a central region, an outer region, and a raised frame region between the central region and the outer region is disclosed. The bulk acoustic wave resonator can include a piezoelectric layer and a top electrode over the piezoelectric layer. The top electrode is disposed at least in the central region, the outer region, and the raised frame region. The top electrode is configured such that a resonant frequency in the outer region is higher than a resonant frequency in the central region.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/251,849, filed Oct. 4, 2021, titled “BULK ACOUSTIC WAVE RESONATOR WITH MODIFIED OUTER REGION,” are hereby incorporated by reference under 37 CFR 1.57 in their entirety.

### BACKGROUND

### Field

Embodiments of this disclosure relate to bulk acoustic wave (BAW) resonators, and in particular to BAW resonators having a reduced perimeter leakage structure.

### Description of the Related Technology

Bulk acoustic wave (BAW) resonators are a type of acoustic device used in a number of applications including radio-frequency modules and wireless devices, such as filters. A quality factor Q is a measurement of the energy lost in a resonator per oscillation. Therefore, BAW resonators with a high Q lose less energy than those with a lower Q.

Energy is often lost at the edges of a BAW resonator where it is ineffectively contained and is thus transmitted to outside of an active region of the BAW resonator. Such energy losses lower the Q of a BAW resonator and reduce the efficiency of a component and/or a module comprising the BAW resonator.

### SUMMARY

According to one embodiment there is provided a bulk acoustic wave resonator comprising a piezoelectric layer, a top electrode disposed on a first surface of the piezoelectric layer; the bulk acoustic wave resonator having a central region, a first outer region, and a first raised frame region between the central region and the first outer region; the top electrode having a first thickness within the central region, a second thickness within the first raised frame region, and a third thickness within the first outer region, the second thickness being greater than both the first thickness and the third thickness.

In one example, the first thickness and the third thickness are substantially the same.

In one example, the bulk acoustic wave resonator further has a tapered raised frame region between the central region and the first raised frame region, the thickness of the top electrode varying within the tapered raised frame region from the first thickness to the second thickness.

In one example, the bulk acoustic wave resonator further comprises a first dielectric layer between the top electrode and the piezoelectric layer, the first dielectric layer extending within the first raised frame region and the first outer region.

In one example, the bulk acoustic wave resonator further comprises a bottom electrode disposed on a second surface of the piezoelectric layer.

In one example, the bottom electrode extends on the second surface of the piezoelectric layer within the central region and the first raised frame region.

In one example, the bottom electrode terminates in a taper.

In one example, the taper begins or ends at the boundary between the first raised frame region and the first outer region.

In one example, the bottom electrode terminates within the first raised frame region or the first outer region.

In one example, the bulk acoustic wave resonator further comprises a substrate and an air cavity disposed between the substrate and the bottom electrode.

In one example, the air cavity has a constant thickness within the central region.

In one example, the bulk acoustic wave resonator is a mesa type bulk acoustic wave resonator, the air cavity terminating in a taper.

In one example, the taper begins or ends at within the raised frame region.

In one example, the bulk acoustic wave resonator further comprises a second outer region and a second raised frame region disposed between the central region and the second outer region, the central region being disposed between the first raised frame region and the second raised frame region; the top electrode having fourth thickness within the second raised frame region, the fourth thickness being greater than the first thickness.

In one example, the second thickness and the fourth thickness are substantially the same.

In one example, the top electrode terminates between the second raised frame region and the second outer region.

In one example, the total thickness of the bulk acoustic wave resonator in the first outer region is similar to, or the same as, the total thickness of the bulk acoustic wave resonator in the second outer region.

In one example, the total thickness of the bulk acoustic wave resonator in the first outer region is within 5%, 10% or 15% of the total thickness of the bulk acoustic wave resonator in the second outer region.

In one example, the bottom electrode extends on the second surface of the piezoelectric layer within the central region, the second raised frame region and the second outer region.

In one example, the bulk acoustic wave resonator further having one or more recessed frame regions between the first raised frame region and the central region and/or between the second raised frame region and the central region.

In one example, the thickness of the top electrode is the same in the one or more recessed frame regions and the central region.

In one example, the bulk acoustic wave resonator further comprises a dielectric layer disposed on a surface of the top electrode opposite the piezoelectric layer, the dielectric layer being thicker within the central region than within the one or more recessed frame regions.

In one example, the top electrode comprises a first metal and a second metal.

In one example, the first raised frame region comprises a layer of the first metal and a layer of the second metal having a total thickness of the second thickness, and wherein the first outer region comprises a layer of only the first metal or only the second metal having a thickness of the third thickness.

In one example, the first metal and the second metal are selected from the list of ruthenium and molybdenum.

According to another embodiment there is provided a die comprising a bulk acoustic wave resonator, the bulk acoustic wave resonator having a piezoelectric layer; a top electrode disposed on a first surface of the piezoelectric layer; the bulk acoustic wave resonator having a central region, a first outer region, and a first raised frame region between the central region and the first outer region; the top electrode having a first thickness within the central region, a second thickness within the first raised frame region, and a third thickness within the first outer region, the second thickness being greater than both the first thickness and the third thickness.

According to another embodiment there is provided a filter comprising one or more bulk acoustic wave resonators, each bulk acoustic wave resonator having a piezoelectric layer; a top electrode disposed on a first surface of the piezoelectric layer; the bulk acoustic wave resonator having a central region, a first outer region, and a first raised frame region between the central region and the first outer region; the top electrode having a first thickness within the central region, a second thickness within the first raised frame region, and a third thickness within the first outer region, the second thickness being greater than both the first thickness and the third thickness.

According to another embodiment there is provided a radio-frequency module comprising a packaging substrate configured to receive a plurality of devices; and a die mounted on the packaging substrate, the die having a bulk acoustic wave resonator, the bulk acoustic wave resonator having a piezoelectric layer; a top electrode disposed on a first surface of the piezoelectric layer; the bulk acoustic wave resonator having a central region, a first outer region, and a first raised frame region between the central region and the first outer region; the top electrode having a first thickness within the central region, a second thickness within the first raised frame region, and a third thickness within the first outer region, the second thickness being greater than both the first thickness and the third thickness.

According to another embodiment there is provided a wireless mobile device comprising one or more antennas; and a radio-frequency module that communicates with the one or more antennas, the radio-frequency module having a die including a bulk acoustic wave resonator, the bulk acoustic wave resonator having a piezoelectric layer; a top electrode disposed on a first surface of the piezoelectric layer; the bulk acoustic wave resonator having a central region, a first outer region, and a first raised frame region between the central region and the first outer region; the top electrode having a first thickness within the central region, a second thickness within the first raised frame region, and a third thickness within the first outer region, the second thickness being greater than both the first thickness and the third thickness.

In one aspect, a bulk acoustic wave resonator having a central region, an outer region, and a raised frame region between the central region and the outer region is disclosed. The bulk acoustic wave resonator can include a piezoelectric layer, and a top electrode over the piezoelectric layer. The top electrode is disposed at least in the central region, the outer region, and the raised frame region. The top electrode includes a first layer and a second layer. A material of the first layer is different from the material of the second layer.

In one embodiment, the top electrode in the raised frame region includes the first and second layers. The top electrode in the central region can consist of the first layer. The top electrode in the outer region can consist of the first layer or the second layer. The first layer continuously can extend at least from the central region to the outer region. The second layer can be disposed over the first layer in the raised frame region. The second layer can be disposed between the first layer and the piezoelectric layer in the raised frame region. The first layer can continuously extend at least from the central region to the raised frame region. The second layer can extend at least from the raised frame region to the outer region.

In one embodiment, the bulk acoustic wave resonator further includes a bottom electrode disposed such that the piezoelectric layer is positioned between the top electrode and the bottom electrode. An end of the bottom electrode where the bottom electrode terminates can be positioned in the raised frame region or the outer region. The end of the bottom electrode can be positioned within 1 μm from an intersection between the raised frame region and the outer region. The bulk acoustic wave resonator can be a mesa type bulk acoustic wave resonator and further include a substrate and an air cavity that is disposed between the substrate and the bottom electrode.

In one embodiment, materials of the first layer and the second layer are selected from molybdenum (Mo), tungsten (W), platinum (Pt), ruthenium (Ru), iridium (Ir), or osmium (Os).

In one aspect, a bulk acoustic wave resonator is disclosed. The bulk acoustic wave resonator can include a top electrode having a first portion and a second portion that has a different material from the first portion, a bottom electrode, and a piezoelectric layer between the first electrode and the second electrode.

In one embodiment, the bulk acoustic wave resonator has a central region, a first outer region, a second outer region, a first raised frame region between the central region and the first outer region, and a second raised frame region between the central region and the second outer region. The top electrode can extend from the first outer region through the first raised frame region, the central region, and the second raised frame region, and terminate with an intersection between the second raised frame region and the second outer region. The bottom electrode can extend from the second outer region through the second raised frame region and the central region, and terminate in the first raised frame region or the first outer region. The first portion of the top electrode can continuously extend at least from the central region to the first outer region. The second portion of the top electrode can be disposed over the first portion in the first raised frame region. The second layer can be disposed between the first portion and the piezoelectric layer in the first raised frame region. The first portion can continuously extend at least from the central region to the first raised frame region, and the second portion can extend at least from the first raised frame region to the outer region. A layout of the first and second portions of the top electrode in the first raised frame region can be the same as a layout of the first and second portions of the top electrode in the second raised frame region.

A bulk acoustic wave resonator having a central region, an outer region, and a raised frame region between the central region and the outer region is disclosed. The bulk acoustic wave resonator can include a piezoelectric layer and a top electrode over the piezoelectric layer. The top electrode is disposed at least in the central region, the outer region, and the raised frame region. The top electrode is configured such that a resonant frequency in the outer region is higher than a resonant frequency in the central region.

In one embodiment, an resonant frequency in the raised frame region is lower than the resonant frequencies in the central region and the outer region. A thickness of the top electrode in the raised frame region can be greater than a thickness of the top electrode in the center region and a thickness of the top electrode in the outer region. The top electrode in the raised frame region can include a first layer and a second layer. Materials of the first layer and the second layer are selected from molybdenum (Mo), tungsten (W), platinum (Pt), ruthenium (Ru), iridium (Ir), or osmium (Os).

In one embodiment, the bulk acoustic wave resonator further includes a bottom electrode is disposed such that the piezoelectric layer is positioned between the top electrode and the bottom electrode. An end of the bottom electrode where the bottom electrode terminates can positioned in the raised frame region or the outer region. The end of the bottom electrode can be positioned within 1 μm from an intersection between the raised frame region and the outer region. The bulk acoustic wave resonator can be a mesa type bulk acoustic wave resonator and further include a substrate and an air cavity that is disposed between the substrate and the bottom electrode. A bulk acoustic wave resonator having a central region, a first outer region, a second outer region, a first raised frame region between the central region and the first outer region, and a second raised frame region between the central region and the second outer region is disclosed. The bulk acoustic wave resonator can include a top electrode having a first portion and a second portion that has a different material from the first portion, a bottom electrode, and a piezoelectric layer between the first electrode and the second electrode. An resonant frequency in the first and second outer regions are higher than an resonant frequency in the central region.

In one embodiment, an resonant frequency in the first raised frame region and an resonant frequency in the second raised frame region are lower than the resonant frequencies in the central region and the first and second outer regions. A thickness of the top electrode in the first raised frame region can be greater than a thickness of the top electrode in the center region and a thickness of the top electrode in the first outer region. The top electrode in the raised frame region can include a first layer and a second layer. Materials of the first layer and the second layer can be selected from molybdenum (Mo), tungsten (W), platinum (Pt), ruthenium (Ru), iridium (Ir), or osmium (Os). The resonant frequency in the first raised frame region and the resonant frequency in the second raised frame region can be substantially the same. The resonant frequency in the first outer region and the resonant frequency in the second outer region can be substantially the same.

In one embodiment, the top electrode extends from the first outer region through the first raised frame region, the central region, and the second raised frame region, and terminates with an intersection between the second raised frame region and the second outer region. The bottom electrode can extend from the second outer region through the second raised frame region and the central region, and an end of the bottom electrode where the bottom electrode terminates can be positioned in the first raised frame region or the first outer region. The end of the bottom electrode can be positioned within 1 μm from an intersection between the raised frame region and the outer region. The bulk acoustic wave resonator can be a mesa type bulk acoustic wave resonator and further include a substrate and an air cavity that is disposed between the substrate and the bottom electrode. The bulk acoustic wave resonator can further include a dielectric layer disposed over the top electrode. The dielectric layer can be thicker in the central region than in a recessed frame region between the central region and the first raised frame region.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

The present disclosure relates to U.S. Patent Application No. ______ [Attorney Docket SKYWRKS.1256A1], titled “BULK ACOUSTIC WAVE RESONATOR WITH MODIFIED OUTER REGION,” filed on even date herewith, U.S. Patent Application No. ______ [Attorney Docket SKYWRKS.1256A2], titled “BULK ACOUSTIC WAVE RESONATOR WITH MULTILAYEY ELECTRODE,” filed on even date herewith, the entire disclosure of which are hereby incorporated by reference herein.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure.

FIG. 1 is a schematic cross sectional side view of a bulk acoustic wave (BAW) resonator.

FIG. 2 is a graph showing a frequency response of a BAW resonator.

FIG. 3 is a graph showing dispersion curves of a central region of a BAW resonator.

FIG. 4 is a graph showing dispersion curves of a raised frame region of a BAW resonator.

FIG. 5 is a graph showing dispersion curves of an outer region of a BAW resonator.

FIG. 6 is a graph showing dispersion curves of another outer region of a BAW resonator.

FIG. 7 is a schematic cross sectional side view of a BAW according to an embodiment.

FIG. 8 is a graph showing dispersion curves of an outer region of the BAW resonator of FIG. 7.

FIG. 9A is a schematic cross sectional side view of a portion of a BAW according to an embodiment.

FIG. 9B is a schematic cross sectional side view of a portion of a BAW according to an embodiment.

FIG. 9C is a schematic cross sectional side view of a portion of a BAW according to an embodiment.

FIG. 9D is a schematic cross sectional side view of a portion of a BAW according to an embodiment.

FIG. 10 is a schematic cross sectional side view of a portion of a BAW according to an embodiment.

FIG. 11 is a schematic cross sectional side view of a portion of a BAW according to an embodiment.

FIG. 12 is a schematic cross sectional side view of a portion of a BAW according to an embodiment.

FIG. 13 is a filter according to an embodiment.

FIG. 14 is a radio-frequency front end module according to an embodiment.

FIG. 15 is a wireless device according to an embodiment.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Aspects and embodiments described herein are directed to a bulk acoustic wave (BAW) resonator having an improved performance and higher Q factor, in particular due to reduced energy leakage or dissipation at the outer regions of the BAW.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

A bulk acoustic wave (BAW) resonator is a form of acoustic wave resonator that generally includes a layer of piezoelectric material positioned or sandwiched between a top and a bottom electrode and suspended over a cavity that allows for the layer of piezoelectric material to vibrate. A signal applied across the top and bottom electrodes causes an acoustic wave to be generated in and travel through the layer of piezoelectric material. A BAW resonator exhibits a frequency response to applied signals with a resonance peak based at least in part on a thickness of the film of piezoelectric material. The primary acoustic wave generated in a BAW resonator is an acoustic wave that travels through the layer of piezoelectric material in a direction generally perpendicular to layers of conducting material forming the top and bottom electrodes.

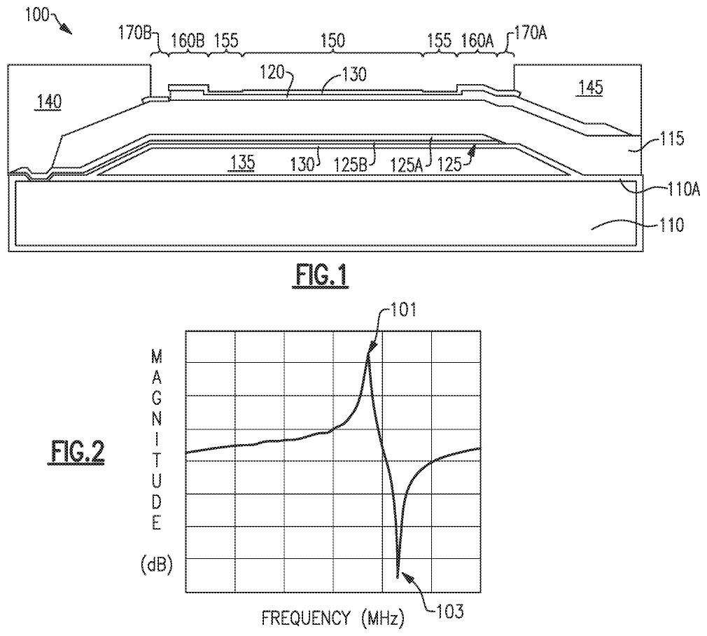

FIG. 1 is a schematic cross-sectional side view of an example of a BAW resonator 100. The BAW resonator 100 is disposed on a substrate 110, for example, a silicon substrate that may include a dielectric surface layer 110A of, for example, silicon dioxide. The BAW resonator 100 includes a layer or film of piezoelectric material 115, for example, aluminum nitride (AlN). A top electrode 120 is disposed on top of a portion of the layer or film of piezoelectric material 115 and a bottom electrode 125 is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a seed layer 125B, for example of titanium (Ti), disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110, and is an air cavity. A bottom electrical contact 140 formed of, for example, copper may make electrical connection with the bottom electrode 125 and a top electrical contact 145 formed of, for example, copper may make electrical connection with the top electrode 120.

The BAW resonator 100 may include a central region 150 including a main active domain in the layer or film of piezoelectric material 115 in which a main acoustic wave is excited during operation. Recessed frame regions 155 may bound and define the lateral extent of the central region 150. The recessed frame regions 155 may be defined by areas that have a thinner layer of dielectric material 130 on top of the top electrode 120 than in the central region 150. The layer of dielectric material 130 in the recessed frame regions 155 may be from about 10 nm to about 100 nm thinner than the layer of dielectric material 130 in the central region 150 and/or the difference in thickness of the dielectric material in the recessed frame regions 155 vs. in the central region 150 may cause the resonant frequency of the device in the recessed frame regions 155 to be between about 5 MHz to about 50 MHz higher than the resonant frequency of the device in the central region 150.

A raised frame region 160A, 160B may be defined on opposite sides of the recessed frame regions 155 from the central region 150 and may directly abut the outside edges of the recessed frame regions 155. The raised frame regions 160A, 160B may be defined by areas where the top electrode 120 is thicker than in the central region 150 and in the recessed frame regions 155. The top electrode 120 may have the same thickness in the central region 150 and in the recessed frame regions 155 but a greater thickness in the raised frame regions 160A, 160B. The top electrode 120 may be between about 50 nm and about 500 nm thicker in the raised frame regions 160A, 160B than in the central region 150 and/or in the recessed frame regions 155. The raised frame regions may be, for example, 1 μm or more in width, or 4 μm or more in width.

Beyond the raised frame region 160B, that is, on an opposite side to the central region 150, on one side of the BAW resonator is an outer region 170B. The top electrode 120 terminates at the boundary between the raised frame region 160B and the outer region 170B, such that the top electrode 120 does not extend into the outer region 170B. Another outer region 170A is disposed at the opposite side of the BAW resonator from outer region 170B. In this outer region 170A, the top electrode 120 continues from the raised frame region 160A (without changing thickness), whereas the bottom electrode 125 terminates.

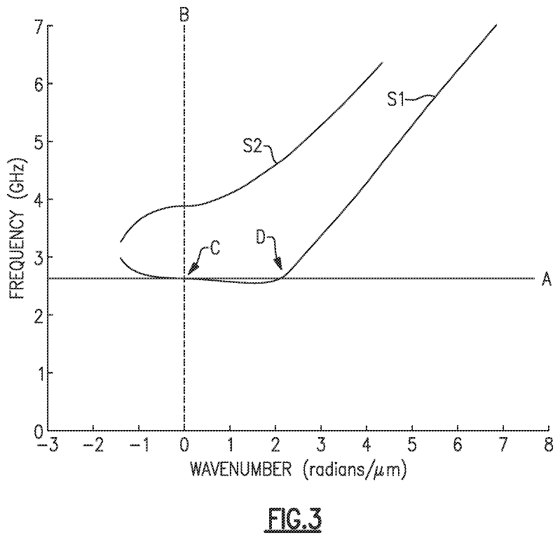

FIG. 2 illustrates the frequency response of a typical BAW resonator, such as the BAW resonator described with respect to FIG. 1. It can be seen in FIG. 2 that the BAW resonator displays a resonance 101 and an anti-resonance 103 at nearby frequencies.

The recessed frame regions 155 and the raised frame regions 160A, 160B may contribute to dissipation or scattering of transverse acoustic waves generated in the BAW resonator 100 during operation and/or may reflect transverse waves propagating outside of the recessed frame regions 155 and the raised frame regions 160A, 160B and prevent these transverse acoustic waves from entering the central region and inducing spurious signals in the main active domain region of the BAW resonator 100. Without being bound to a particular theory, it is believed that due to the thinner layer of dielectric material 130 on top of the top electrode 120 in the recessed frame regions 155, the recessed frame regions 155 may exhibit a higher velocity of propagation of acoustic waves than the central region 150. Conversely, due to the increased thickness and mass of the top electrode 120 in the raised frame regions 160A, 160B, the raised frame regions 160A, 160B may exhibit a lower velocity of propagation of acoustic waves than the central region 150 and a lower velocity of propagation of acoustic waves than the recessed frame regions 155. The discontinuity in acoustic wave velocity between the recessed frame regions 155 and the raised frame regions 160A, 160B creates a barrier that scatters, suppresses, and/or reflects transverse acoustic waves.

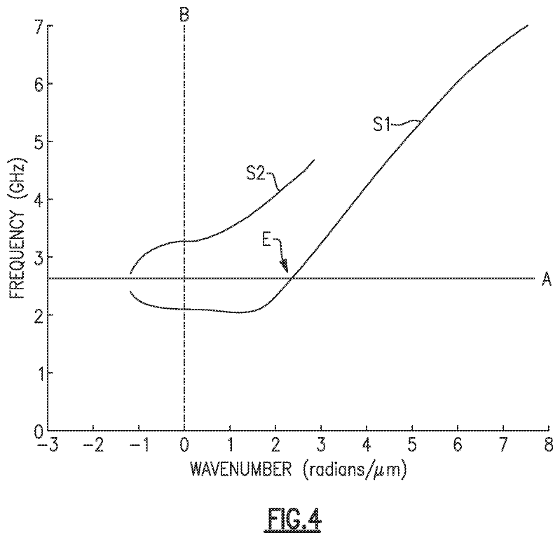

It has been found that the boundary between the raised frame region 160B and the outer region 170B also provides an effective barrier, reflecting acoustic waves back towards the central region 150 and preventing energy from being lost to the external environment. However, boundary between the raised frame region 160A and outer region 170A have been found to be less effective at reflecting acoustic waves. This can be seen by looking at the dispersion curves illustrated in FIGS. 3-6.

FIG. 3 is a graph showing representative dispersion curves within the central region 150 of the BAW resonator 100, showing the S1 and S2 (symmetric) wave modes. The resonant frequency of the BAW resonator 100 is illustrated by line A, lying around 2.7 GHz. The dotted line B corresponds to wavenumber 0. It is noted that the negative wavenumbers on the x-axis correspond to imaginary wavenumbers (e.g., exponentially decaying waves). Hence, everything to the left of the dotted line B, with negative (imaginary) wavenumbers, corresponds to a wave that is not propagating and instead has an exponential decay, whilst everything to the right of the dotted line B, with positive (real) wavenumbers, corresponds to a wave that is propagating.

It can be seen that the S1 mode has a frequency of the resonant frequency of the BAW resonator 100 at a wavenumber of 0, at point C, also crossing the line of the resonant frequency again at point D, corresponding to a wavenumber of around 2. The span of the S1 mode between points C and D is particularly effective to the electric field within the central region 150, especially at the lower wavenumbers, allowing the wave to easily propagate within the central region 150 as desired.

FIG. 4 is a graph showing a dispersion curves of the S1 and S2 modes of the BAW resonator 100 within the raised frame regions 160A, 160B. The graph of FIG. 4 indicates the effect of the raised frame regions 160A, 160B. Due to the thickening of the BAW resonator 100 within the raised frame regions 160A, 160B and the increased amount of metal in the top electrode 120, the frequencies of the waves that can propagate within raised frame regions 160A, 160B are lowered. This is indicated in FIG. 4.

As shown in FIG. 4, due to the lowering of the frequencies, line A, representing the resonant frequency of the BAW resonator 100, passes through the gap between the S1 and S2 modes. The S1 mode does not cross the resonant frequency until a wavenumber of around 2.5. This gives a weak coupling between the electromagnetic field and the BAW resonator 100 in the raised frame regions 160A, 160B, meaning that the lower wavenumber waves cannot propagate in the raised frame regions 160A, 160B and are thus reflected back into the central region 150. However, some energy will reach the outer edges of the raised frame regions 160A, 160B, where the raised frame regions 160A, 160B join the outer regions 170A, 170B.

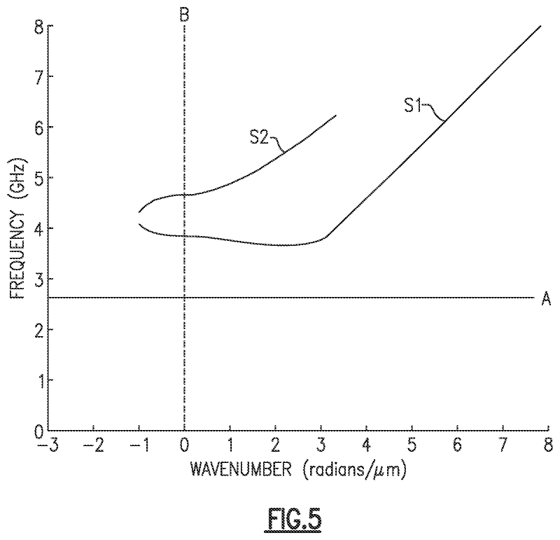

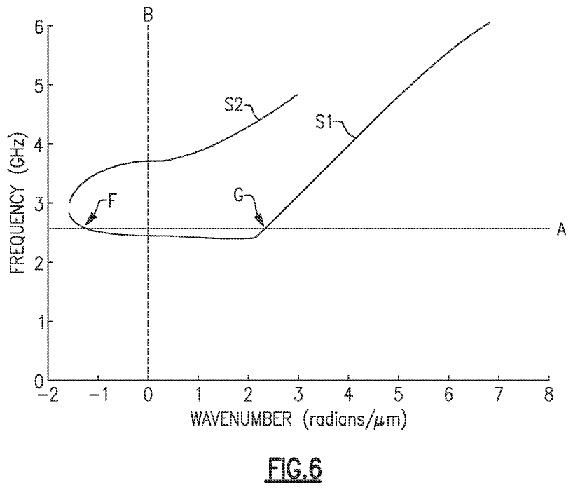

At this boundary, it is desirable to ensure that as much of the incident energy is reflected back towards the central region 150 to minimize losses. At the boundary between raised frame region 160B and outer region 170B, where the top electrode 120 terminates, the boundary effectively reflects energy back towards the central region. This is illustrated by FIG. 5. FIG. 5 is a dispersion graph showing the S1 and S2 modes within the outer region 170B.

As shown in FIG. 5, both the S1 and S2 modes have frequencies that lie well above line A, the resonant frequency of the BAW resonator 100, and do not cross the line A. The coupling between the electromagnetic field and the outer region 170B is therefore very weak in this region and it is very difficult for energy to propagate through the outer region 170B. Hence, the majority of the energy incident on the boundary between the raised frame region 160B and the outer region 170B is reflected back towards the central region 150.

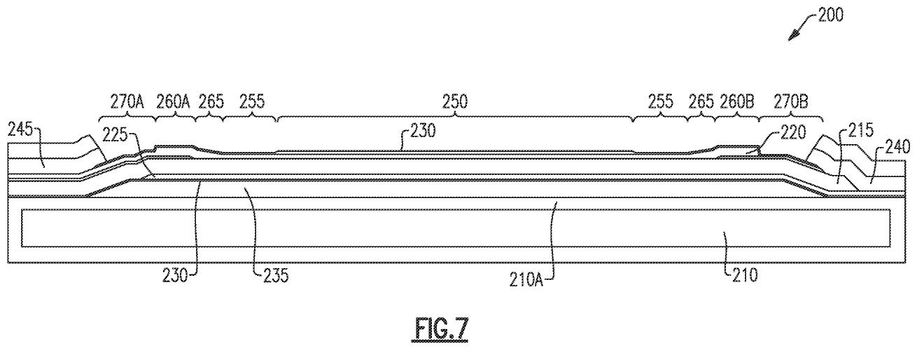

In the other side of the BAW resonator 100, between raised frame region 160A and outer region 170A, where the bottom electrode 125 terminates but the top electrode 120 continues, energy is less effectively reflected. FIG. 6 shows a dispersion graph with the S1 and S2 modes in the outer region 170A.

FIG. 6 shows that the S1 mode only crosses line A, the resonant frequency of the BAW resonator 100, at points F and G, and so the corresponding wavenumbers at these points are the waves that will carry the most energy in this region. The wavenumber at point G is relatively high, approximately 2.5, and the wavenumber at point F is imaginary (about −1 on the graph). However, in between these two points, the frequency of the S1 mode is very similar to the resonant frequency, and so these wavenumber waves will still carry a non-negligible amount of energy out of the BAW resonator 100. Furthermore, given the finite size of the outer region 170A, whilst the wave at point F is a decaying wave due to the negative (imaginary) wavenumber, at the end of the outer region 170A some energy will reach the outer edge of the BAW resonator 100 and then be able to propagate away. By modifying the raised frame region 160A and/or the outer region 170A, the present disclosure provides a boundary better able to reflect more energy back towards the central region 150.

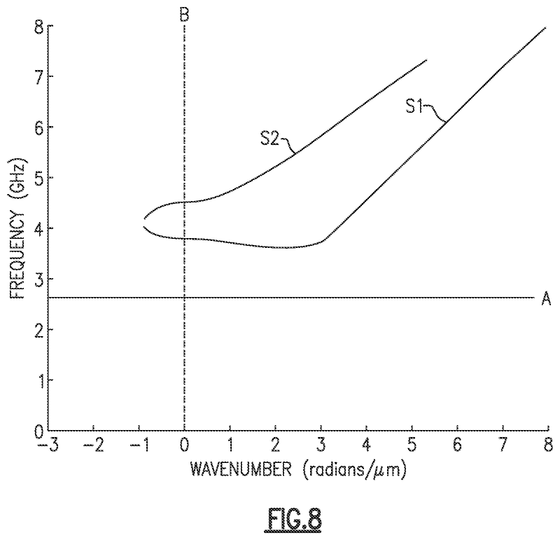

FIG. 7 is cross-sectional view of a BAW resonator 200 according to an embodiment. The BAW resonator 200 can be a mesa type BAW device. The BAW resonator 200 is disposed on a substrate 210. For example, the substrate 210 can include a silicon wafer or substrate. In some embodiments, a high-resistivity silicon (HRS) can be used for the substrate 210 to implement a relatively high performance resonator. A dielectric surface layer 210A (e.g., a silicon dioxide layer) can be disposed on a surface of the substrate 210. For example, the dielectric surface layer 210A can at least partially or completely surround the substrate 210. The BAW resonator 200 can include a piezoelectric layer 215 (e.g., an aluminum nitride (AlN) layer), a top, or first, electrode 220 that is disposed on a top side of a portion of the piezoelectric layer 215, and a bottom, or second, electrode 225 that is disposed on a bottom side of a portion of the piezoelectric layer 215. In some embodiments, the top electrode 220 may include ruthenium (Ru). The bottom electrode 225 may include the same or different material from the material of the top electrode 220. For example, the bottom electrode 225 can include Ru. In some embodiments, the bottom electrode 225 can include a seed layer, such as a titanium (Ti) layer. In a method of forming the bottom electrode 225, the seed layer can be formed prior to forming bulk of the bottom electrode 225. Each of the top electrode 220 and the bottom electrode 225 can be covered with the layer of dielectric material 230 (e.g., a silicon dioxide layer). A cavity 235 can be defined between the bottom electrode 225 and the substrate 210. The cavity 235 can be an air cavity. The BAW resonator 200 can include a bottom electrical contact 240 and a top electrical contact 245. The bottom electrical contact 240 can include, for example, copper, and makes electrical connection with the bottom electrode 225. The top electrical contact 245 can include, for example, copper, and makes electrical connection with the top electrode 220.

The BAW resonator 200 includes a central region 250 that can define a main active domain in the piezoelectric layer 215 in which a main acoustic wave is excited during operation. The top electrode 220 has a first thickness within the central region 250. A recessed frame region 255 bounds and defines the lateral extent of the central region 250. The central region 250 can be positioned laterally between the recessed frame regions 255. The recessed frame regions 255 are defined by areas that have a thinner layer of dielectric material 230 on top of the top electrode 220 than in the central region 250, though the thickness of the top electrode 220 is unchanged from the central region 250. The layer of dielectric material 230 in the recessed frame region 255 may be from about 10 nm to about 100 nm thinner than the layer of dielectric material 230 in the central region 250 and/or the difference in thickness of the dielectric material in the recessed frame region 255 vs. in the central region 250 may cause the resonant frequency of the device in the recessed frame region 255 to be between about 5 MHz to about 50 MHz higher than the resonant frequency of the device in the central region 250.

Raised frame regions 260A, 260B are defined on opposite sides of the recessed frame regions 255 from the central region 250 and are connected to the central region 250 by tapered raised frame regions 265. The central region 250 and the recessed regions 255 can be positioned laterally between the tapered raised frame regions 265, and the tapered raised frame regions 265 can be positioned laterally between the recessed regions 255 and the raised frame regions 260A, 260B. The raised frame regions 260A, 260B can be defined by areas where the top electrode 220 has a second thickness that is thicker than the first thickness of the central region 250 and the recessed frame region 255. That is, the top electrode 220 has the same thickness in the central region 250 and in the recessed frame region 255 but a greater thickness in the raised frame regions 260A, 260B. The second thickness of the top electrode 220 may be between about 50 nm and about 500 nm thicker in the raised frame regions 260A, 260B than the first thickness of the top electrode 220 in the central region 250 and/or in the recessed frame regions 255. A width of the raised frame regions 260A, 260B can depend at least in part on the frequency of operation. The raised frame regions 260A, 260B may be, for example, 1 μm or more in width, or 4 μm or more in width. For example, the width of the raised frame regions 260A, 260B can be in a range of 1 μm to 5 μm, 1 μm to 10 μm, or 1.5 μm to 3 μm. Preferably both the raised frame regions 260A, 260B have the same or generally similar width. In some embodiments, the width of the raised frame region 260A can be within 1 μm of the width of the raised frame region 260B. In the tapered raised frame regions 265, the top electrode 220 can have a thickness that varies from the first thickness of the top electrode 220 in the central region 250 and the recessed frame regions 255 to the second thickness of the top electrode 220 in the raised frame regions 260A, 260B. Preferably, the thickness varies in a linear manner to provide a constant increase in thickness of the top electrode 220 through the tapered raised frame regions 265 from the first thickness at the boundary with the recessed frame regions 255 to the second thickness at the boundary with the raised frame regions 260A, 260B.

The BAW resonator 200 can include a dielectric layer 231 at least partially between the piezoelectric layer 14 and the top electrode 220. For example, the dielectric layer 231 can be positioned in the raised frame regions 260A, 260B. The dielectric layer 231 can include, for example, a SiO₂ layer, a SiN layer, a SiC layer, or any other suitable low acoustic impedance material.

Beyond the raised frame region 260B (e.g., on an opposite side to the central region 250) on one side of the BAW resonator is an outer region 270B. The raised frame region 260B can be positioned laterally between the tapered raised frame regions 265 and the outer region 270B. The top electrode 220 terminates at the boundary between the raised frame region 260B and the outer region 270B, such that the top electrode 220 does not extend into the outer region 270B. An end of the top electrode 220 where the top electrode terminates can have a tapered shape. The bottom electrode 225, on the other hand, extends throughout the outer region 270B to contact the bottom electrical contact 240. Another outer region 270A is disposed at the opposite side of the BAW resonator from outer region 270B. The raised frame region 260A can be positioned laterally between the tapered raised frame regions 265 and the outer region 270A. In the outer region 270A, the top electrode 220 continues from the raised frame region 260A to contact the top electrical contact 245, whereas the bottom electrode 225 terminates. In some embodiments, the bottom electrode 225 can terminate at or near an intersection between the raised frame region 260A and the outer region 270A. For example, the bottom electrode 225 can terminate within 1 μm from the intersection between the raised frame region 260A and the outer region 270A. An end of the bottom electrode 225 where the bottom electrode terminates can have a tapered shape. However, unlike in previous BAW resonators, such as that illustrated in FIG. 1, in the BAW resonator 200 of FIG. 7, the top electrode 220 has a third thickness in the outer region 270A, which is less than the second thickness of the raised frame region 260A. When the third thickness is less than the second thickness, a wavelength in the outer region 270A can be closer to a wavelength in the outer region 270B, as compared to when the third thickness is equal to or greater than the second thickness. In some embodiments, structures of the recessed regions 255, the tapered raised frame regions 265, and the raised frame regions 260A, 260B can be generally symmetrical along a center of the central region 250. For example, the width of the raised frame region 260A can be the same as or generally similar to the width of the raised frame region 260B.

The BAW resonator 200 can include an active region where the piezoelectric layer 215 overlaps the top electrode 220 and the bottom electrode 225. For example, the active region can include the central region 250, the recessed frame regions 255, the tapered raised frame regions 265, and the raised frame regions 260A, 260B.

As illustrated in the embodiment of FIG. 7, the bottom electrode 225 can laterally extend from the bottom electrical contact 240 through the outer region 270B, the raised frame region 260B, the tapered raised frame regions 265, the recessed regions 255, the central region 250, and the raised frame region 260A, to at least a portion of the outer region 270A. The bottom electrode 225 can terminate at or near a portion between the raised frame region 260A and the outer region 270A where the raised frame region 260A terminates. By terminating the raised frame of the top electrode 220 (e.g., between the raised frame region 260A and the outer region 170A) at or near the termination of the bottom electrode 225, lateral propagating modes (e.g., S1-mode) can be cut-off and be prevented or mitigated from escaping or leaking through a perimeter of the top electrode 220. Accordingly, having the raised frame of the top electrode 220 (e.g., between the raised frame region 260A and the outer region 170A) at or near the termination of the bottom electrode 225 can enable the BAW resonator 200 to have a relatively high Q.

The wave that propagates in the central region 250 has a first frequency f1, the wave that propagates in the recessed frame region 255 has a second frequency f2, the wave that propagates in the tapered raised frame regions 265 has a third frequency f3, the wave that propagates in the raised frame regions 260A, 260B has a forth frequency f4, and the wave that propagates in the outer regions 270A, 270B has a fifth frequency f5. The first to fifth frequencies f1-f5 can be referred to as resonant frequencies of the BAW resonator 200. The structures of various embodiments of a BAW resonator (e.g., the BAW resonator 200) disclosed herein can enable the fifth frequency f5 to be higher than the first frequency f1 and/or the second frequency f2. In some embodiments, the fourth frequency f4 can be the lowest and the fifth frequency f5 can be the highest among the five frequencies f1-f5. [0082] As discussed with respect to the BAW resonator 100 of FIG. 1, the recessed frame regions 255 and the raised frame regions 260A, 260B may contribute to dissipation or scattering of transverse acoustic waves generated in the BAW resonator 200 during operation and/or may reflect transverse waves propagating outside of the recessed frame regions 255 and the raised frame regions 260A, 260B and prevent or mitigate these transverse acoustic waves from entering the central region and inducing spurious signals in the main active domain region (e.g., the central region 250) of the BAW resonator 200. Without being bound to a particular theory, it is believed that due to the thinner layer of dielectric material 230 on top of the top electrode 220 in the recessed frame regions 255, the recessed frame regions 255 may exhibit a higher velocity of propagation of acoustic waves than the central region 250. Conversely, due to the increased thickness and mass of the top electrode 220 in the raised frame regions 260A, 260B, the raised frame regions 260A, 260B may exhibit a lower velocity of propagation of acoustic waves than the central region 250 and a lower velocity of propagation of acoustic waves than the recessed frame regions 255. The discontinuity in acoustic wave velocity between the recessed frame regions 255 and the raised frame regions 260A, 260B creates a barrier that scatters, suppresses, and/or reflects transverse acoustic waves. The tapered raised frame regions 265, having varying thicknesses, can help reflect a range of different frequencies of wave due to the range of thicknesses of the BAW resonator within the tapered raised frame regions 265.

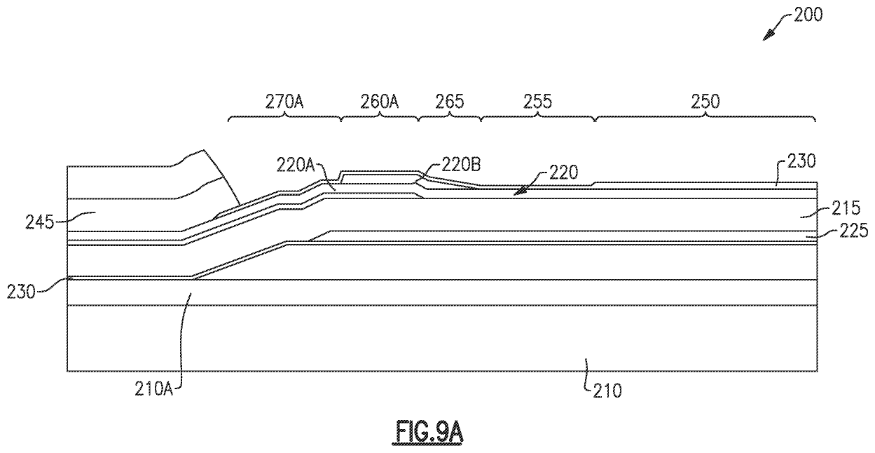

As noted herein, for example, with respect to FIG. 1 and FIG. 5, the boundary between the raised frame region 260B and the outer region 270B can provide an effective barrier, reflecting acoustic waves back towards the central region 250 and preventing or mitigating energy from being lost to the external environment (e.g., outside of the BAW resonator 200). However, compared to the BAW resonator 100 of FIG. 1, the boundary between the raised frame region 260A and the outer region 270A in the BAW resonator 200 provides an improved reflector of acoustic waves. This is illustrated by the dispersion graph of FIG. 8.

In some embodiments, a total thickness of the bulk acoustic wave resonator in the outer region 270A can be generally similar to or the same as a total thickness of the bulk acoustic wave resonator in the outer region 270B. For example, the total thickness of the bulk acoustic wave resonator in the outer region 270A can be within 3%, 5%, 10%, or 15% of the total thickness of the bulk acoustic wave resonator in the second outer region.

FIG. 8 is a graph showing dispersion of the S1 and S2 modes in the BAW resonator 200. FIG. 8 indicates that, with the negative wavenumbers on the x-axis representing imaginary wavenumbers, the S1 and S2 modes are shifted well above line A, the resonant frequency of the BAW resonator 200. There is hence significantly small coupling between the electromagnetic field and the BAW resonator 200 in the outer region 170A for these modes, preventing or mitigating propagation of these waves and preventing or mitigating energy from escaping.

The graph of FIG. 8 indicates that the decrease in the combined thickness of the bottom electrode 225 and of the top electrode 220 between the raised frame region 260A and the outer region 270A, and between the central region 150 and the outer region 270A can contribute to confining acoustic energy in the active region of the BAW resonator 200. The thickness difference can shift the frequencies of the waves that can propagate within the outer region 270A to higher frequencies, making it more difficult for waves having the resonant frequency of the BAW resonator 200 from propagating within the outer region 270A. As waves having the resonant frequency of the BAW resonator 200 carry the majority of the energy in the BAW resonator 200, by preventing or mitigating the propagation of these waves then losses can be effectively prevented or mitigated due to acoustic waves leaving the BAW resonator 200 and dissipating outside of the central region 250.

Preferably, the thickness of the piezoelectric layer 215, the top electrode 220, and the layer of dielectric material 230 in the outer region 270A is similar to, or the same as, the thickness of the piezoelectric layer 215, the bottom electrode 225, and the layer of dielectric material 230 in the outer region 270B. Having the same or similar thicknesses for the outer regions 270A, 270B of the BAW resonator 200 can provide the same or similar acoustic properties in the outer regions 270A, 270B, and each side of the outer regions 270A, 270B can effectively reflect incident energy back towards the central region 250.

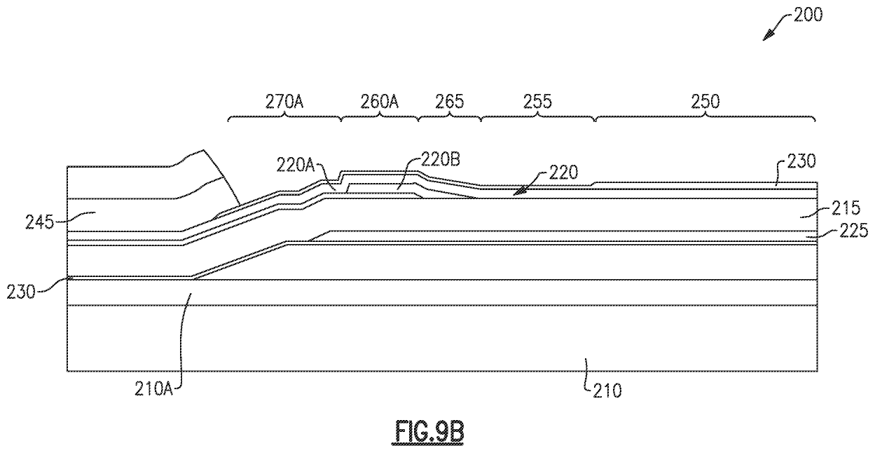

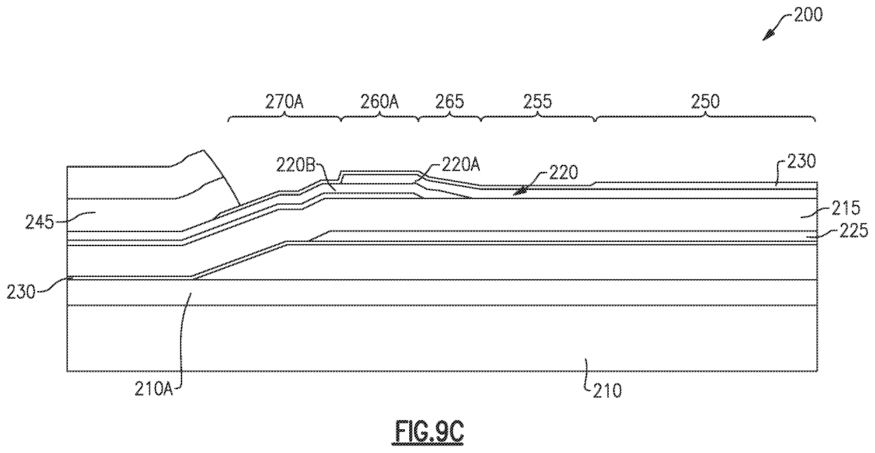

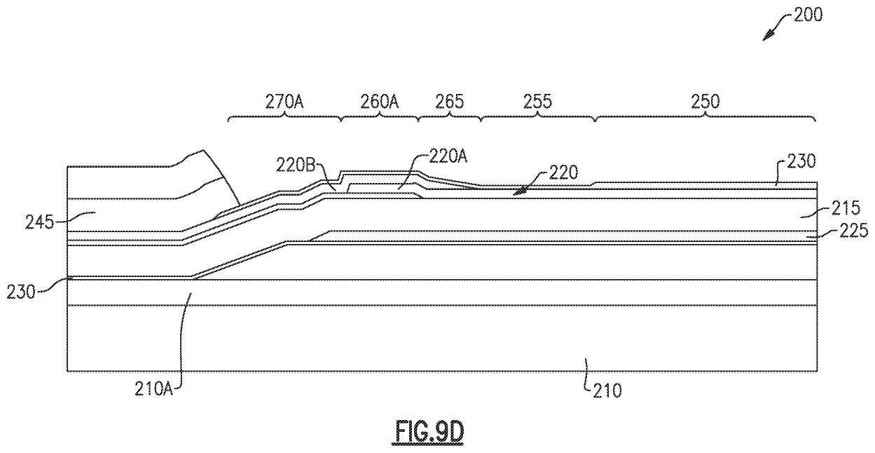

FIGS. 9A-9D illustrate close-up views of BAW resonators 201, 202, 203, 204 according to various embodiments. Unless otherwise noted, components of FIGS. 9A-9D may be the same as or generally similar to like components disclosed herein. In particular, FIGS. 9A-9D highlight the side of the BAW resonators 201, 202, 203, 204 where the outer region 270A joins the raised frame region 260A. Each of FIGS. 9A-9D shows that the thicknesses (e.g., the first thickness and the third thickness) of the top electrode 220 is the same or generally similar in the central region 250, the recessed frame region 255, and the outer region 270A. The thickness of the top electrode 220 increases in the tapered raised frame region 265 towards the raised frame region 260A, and the thickness of the top electrode 220 in the raised frame region 260A (e.g., the second thickness) can be greater than the first and third thicknesses.

As shown in FIGS. 9A-9D, the top electrode 220 can include a multilayer structure that includes a first layer or portion 220A and a second layer or portion 220B. In FIG. 9A, the first portion 220A of the top electrode 220 can have a constant thickness and the second portion 220B can have a varying thickness. The second portion 220B can be disposed over the first portion 220A. The first portion 220A can have a constant thickness of the first thickness and is present throughout each region of the BAW resonator 200 that the top electrode 220 is present in. That is, throughout the outer region 270A, the raised frame region 260A, the tapered raised frame region 265, the recessed frame region 255, and the central region 250. Not shown in FIG. 9A, but as will be appreciated from FIG. 7, the first portion 220A of the top electrode 220 can terminate on one side at the boundary between the raised frame region 260 and the outer region 270B (not shown). On the other side, the first portion 220A is in contact with the top electrical contact 245.

The second portion 220B of the top electrode 220 can be present in the tapered raised frame regions 265 and the raised frame regions 260 (although only one tapered raised frame region 265 and one raised frame region 260A are illustrated in FIG. 9A). The second portion 220B accounts for the additional thickness of the top electrode 220 within the tapered raised frame regions 265 and the raised frame regions 260. The thickness of the second portion 220B can vary in the tapered raised frame regions 265 from zero thickness (i.e., the upper portion 220B begins) at the boundary between the recessed frame region 255 and the tapered raised frame region 265 to its maximum thickness at the boundary between the tapered raised frame region 265 and the raised frame region 260, and continues this maximum thickness throughout the raised frame region 260. In some embodiments, the second portion 220B can have a tapered shape closer to the outer region 270A. This maximum thickness equals the difference between the thickness of the top electrode 220 within the central region 250 and the raised frame region 260. That is, it is the difference between the first (or third) and second thicknesses.

In some embodiments, the first portion 220A and the second portion 220B of the top electrode 220 can include different materials. For example, the material of the first portion 220A and the material of the second portion 220B can have a different etching rate, a different density, and/or a different impedance. In some embodiments, the material of the first portion 220A and the material of the second portion 220B can include one or more of molybdenum (Mo), tungsten (W), platinum (Pt), ruthenium (Ru), iridium (Ir), or osmium (Os). When a material of the second portion 220B has a slower etch rate than a etch rate of a material of the first portion 220A, the first portion 220A in the outer region 270A may be etched with less process than when the material of the second portion 220B has a higher etch rate than the etch rate of the material of the first portion 220A. In some embodiments, the material and thickness of the second portion 220B can be selected based at least in part on resulting frequency differences between the central region 250, the recessed region 255, the tapered raised frame region 265, the raised frame region 260A, and/or the outer region 270A.

In the BAW resonator 202 of FIG. 9B, the second portion 220B of the top electrode 220 can be disposed between the first portion 220A of the top electrode 220 and the piezoelectric layer 215. The first portion 220A can have a constant thickness of the first thickness and can be present throughout each region of the BAW resonator 200 that the top electrode 220 is present within. That is, throughout the outer region 270A, the raised frame region 260A, the tapered raised frame region 265, the recessed frame region 255, and the central region 250. However, it is noted that within the raised frame region 260A and the tapered raised frame region 265 the first portion 220A is disposed over the top of the second portion 220A. Not shown in FIG. 9B, but as will be appreciated from FIG. 7, the first portion 220A of the top electrode 220 terminates on one side at the boundary between the raised frame region 260 and the outer region 270B (not shown). On the other side, the first portion 220A is in contact with the top electrical contact 245.

The second portion 220B of the top electrode 220 can be present in the tapered raised frame regions 265 and the raised frame regions 260 (although only one tapered raised frame region 265 and one raised frame region 260A are illustrated in FIG. 9B). The second portion 220B is disposed between the first portion 220A and the piezoelectric layer 215, and accounts for the additional thickness of the top electrode 220 in the tapered raised frame regions 265 and the raised frame regions 260. The thickness of the second portion 220B varies within the tapered raised frame regions 265 from zero thickness (i.e., the second portion 220B begins) at the boundary between the recessed frame region 255 and the tapered raised frame region 265 to its maximum thickness at the boundary between the tapered raised frame region 265 and the raised frame region 260, and continues this maximum thickness throughout the raised frame region 260. In some embodiments, the second portion 220B can have a tapered shape closer to the outer region 270A. This maximum thickness equals the difference between the thickness of the top electrode 220 within the central region 250 and the raised frame region 260. That is, it is the difference between the first (or third) and second thicknesses.

In the BAW resonator 203 of FIG. 9C, the second portion 220B of the top electrode 220 can extend into the outer region 270A whilst the first portion 220A of the top electrode 220 lies over the second portion 220B within the tapered raised frame region 265 and the raised frame region 260A, and terminates at the boundary between the raised frame region 260A and the outer region 270A. The first portion 220A can have a constant thickness of the first thickness and is present throughout the raised frame region 260A, the tapered raised frame region 265, the recessed frame region 255, and the central region 250. However, unlike the BAW resonators 201, 202 of FIGS. 9A and 9B, the first portion 220A is not present within the outer region 270A. As with FIG. 9B, in the raised frame region 260A and the tapered raised frame region 265, the first portion 220A can be disposed over the top of the second portion 220B. Not shown in FIG. 9C, but as will be appreciated from FIG. 7, the first portion 220A of the top electrode 220 can terminate on the other side of the BAW resonator 200 (i.e. the side not shown) at the boundary between the raised frame region 260 and the outer region 270B.

The second portion 220B of the top electrode 220 can be present within the tapered raised frame regions 265 and the raised frame regions 260 (although only one tapered raised frame region 265 and one raised frame region 260A are illustrated in FIG. 9C), and the outer region 270A. The second portion 220B is disposed between the piezoelectric layer 215 and the first portion 220A in the raised frame region 260A and the tapered raised frame region 265, and accounts for the additional thickness of the top electrode 220 within the tapered raised frame regions 265 and the raised frame regions 260. The thickness of the second portion 220B can vary in the tapered raised frame regions 265 from zero thickness (i.e., the second portion 220B begins) at the boundary between the recessed frame region 255 and the tapered raised frame region 265 to its maximum thickness at the boundary between the tapered raised frame region 265 and the raised frame region 260A, and continues this maximum thickness throughout the raised frame region 260A and outer region 270A. This maximum thickness preferably equals the thickness of the first electrode 220 within the central region 250.

In the BAW resonator 203 of FIG. 9D, the second portion 220B of the top electrode 220 can extend into the outer region 270A, and the first portion 220A of the top electrode 220 can be at least partially disposed between the piezoelectric layer 215 and the second portion 220B in the tapered raised frame region 265 and the raised frame region 260A, and terminates at the boundary between the raised frame region 260A and the outer region 270A. The first portion 220A can have a constant thickness of the first thickness and can be present throughout the raised frame region 260A, the tapered raised frame region 265, the recessed frame region 255, and the central region 250. However, unlike the BAW resonators 201, 202 of FIGS. 9A and 9B, the first portion 220A is not present within the outer region 270A in the BAW resonator 204. As with the BAW resonator 201 of FIG. 9A, within the raised frame region 260A and the tapered raised frame region 265, the first portion 220A can be disposed between the second portion 220B and the piezoelectric layer 215. Not shown in FIG. 9D, but as will be appreciated from FIG. 7, the first portion 220A of the top electrode 220 can terminate on the other side of the BAW resonator 200 (i.e. the side not shown) at the boundary between the raised frame region 260 and the outer region 270B.

The second portion 220B of the top electrode 220 can be present in the tapered raised frame regions 265 and the raised frame regions 260 (although only one tapered raised frame region 265 and one raised frame region 260A are illustrated in FIG. 9D), and the outer region 270A. The second portion 220B can be disposed at least partially over the first portion 220A in the raised frame region 260A and the tapered raised frame region 265, and accounts for the additional thickness of the top electrode 220 within the tapered raised frame regions 265 and the raised frame regions 260. The thickness of the second portion 220B can vary in the tapered raised frame regions 265 from zero thickness (i.e., the second portion 220B begins) at the boundary between the recessed frame region 255 and the tapered raised frame region 265 to its maximum thickness at the boundary between the tapered raised frame region 265 and the raised frame region 260A, and continues this maximum thickness throughout the raised frame region 260A and outer region 270A. This maximum thickness preferably equals the thickness of the first electrode 220 within the central region 250.

In FIGS. 9A-9D, the first portion 220A and the second portion 220B are illustrated as two distinct layers. However, this need not be the case, and the first portion 220A and the second portion 220B may be integral without any physical boundary between them. The first and second portions 220A, 220B may be manufactured together as one layer, or the layers may be former separately one after the other. For example, in the case of FIGS. 9A and 9D, the first portion 220A may be formed first as a uniform layer across the relevant regions of the BAW resonator 200 and then the second portion 220B may be formed on top within the tapered raised frame regions 265, the raised frame regions 260 and the outer region 270A (in the case of FIG. 9D). Alternatively, in the case of FIGS. 9B and 9C, the second portion 220B may be formed first, with the first portion 220A being formed subsequently over the top.

Suitable techniques include photolithographic processes. In such a case, the portion to be formed first may be formed, and then a mask may be used in combination with a photoresist to deposit the portion to be formed second only in the desired region(s). Alternatively, a uniform layer having the second thickness (e.g., the thickness of the raised frame region 260A) may be deposited and then etched away using a photolithographic process to provide the different thicknesses of raised frame region 260A and tapered raised frame region 265.

Whilst it is noted that the first portion and the second portion may be integral, they may also be formed from two distinct layers. For example, they may be formed from different metals. In one example, the first portion 220A is formed from ruthenium (Ru) whilst the second portion 220B is formed from molybdenum (Mo). In other cases, the first portion 220A is formed from molybdenum and the second portion 220B is formed from ruthenium. Molybdenum and ruthenium are preferable materials for portions having a steep edge (such as the edge of the second portion 220B between the raised frame region 260A and the outer region 270A in FIGS. 9A and 9B, of the edge of the first portion 220A between the raised frame region 260A and the outer region 270A in FIGS. 9C and 9D) as it is possible to obtain a strong differential etch.

Though the top electrode 220 with a multilayer structure are shown with two portions or layers (e.g., a dual layer structure), the multilayer structure can include three or more portions or layers as suitable. Some regions of the first and second portions 220A, 220B may be described herein to have a constant thickness. However, in accordance with principle and advantages disclosed herein, the thicknesses of the first and second portions 220A, 220B can be suitably selected. For example, thicknesses of the first and second portions 220A, 220B can be selected to enable the fifth frequency f5 of the wave that propagates in the outer regions 270A, 270B to be higher than the first frequency f1 of the wave that propagates in the central region 250 and/or the second frequency f2 of the wave that propagates in the recessed frame region 255. In some embodiments, the fourth frequency f4 of the wave that propagates in the raised frame regions 260A, 260B can be the lowest and the fifth frequency f5 can be the highest among the five frequencies f1-f5.

In some embodiments, structures of the top electrode 220 in the recessed regions 255, the tapered raised frame regions 265, and the raised frame regions 260A, 260B can be generally symmetrical along a center of the central region 250. For example, the width of the raised frame region 260A can be the same as or generally similar to the width of the raised frame region 260B. For example, a layout or relative positions of the first and second portions 220A, 220B of the top electrode 220 in the raised frame region 260A is the same as a layout or relative positions of the first and second portions 220A, 220B of the top electrode 220 in the second raised frame region 260B.

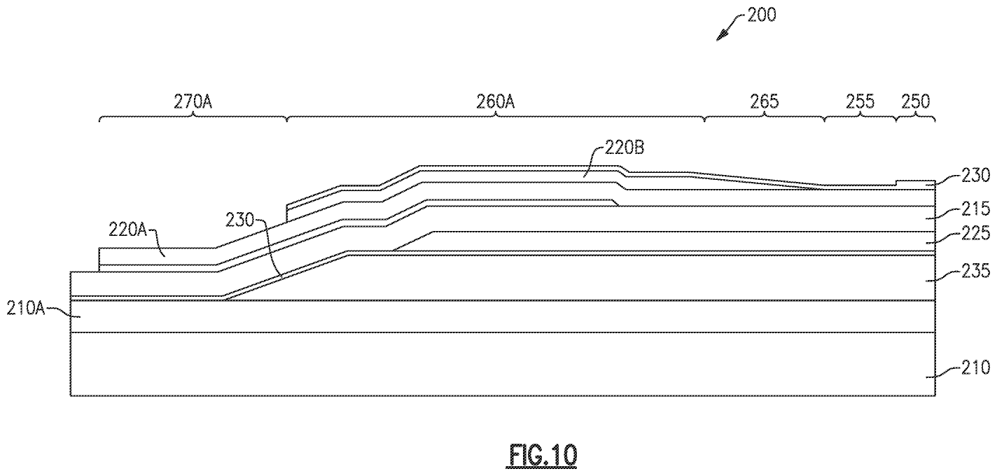

The boundary between the raised frame region 260A and the outer region 270A may be located at a number of positions relative to other components, such as the bottom electrode 225 and the cavity 235, of a BAW resonator. Different examples will now be discussed in relation to FIGS. 10-12.

FIG. 10 is a schematic cross sectional side view of a portion of a BAW resonator 205 according to an embodiment. Unless otherwise noted, components of FIG. 10 may be the same as or generally similar to like components disclosed herein. In some embodiments, the raised frame region 260A can be relatively longer compared to the outer region 270A. FIG. 10 shows that the bottom electrode 225 can terminate in the raised frame region 260A. It can also be seen that the BAW resonator 205 has a mesa type cavity 235, whereby the cavity 235 is formed on top of the substrate 210 (rather than by being recessed into substrate 210). The cavity 235 has a tapered end, and the boundary between the raised frame region 260A and the outer region 270A lies over this tapered portion of the cavity 235.

The raised frame of the top electrode 220 in the raised frame region 260A can extend outwardly beyond the bottom electrode 225 termination. Though FIG. 10 does not illustrate the portion of the BAW resonator 205 near the raised frame region 260B (see FIG. 7), the raised frame of the top electrode 220 in the raised frame region 260B can have a width that is generally similar to the raised frame of the top electrode 220 in the raised frame region 260A.

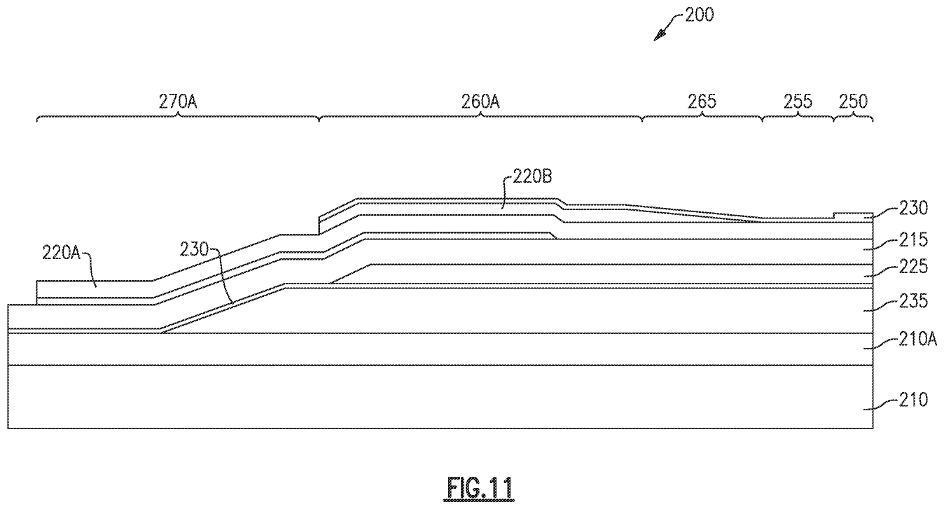

FIG. 11 is a schematic cross sectional side view of a portion of a BAW resonator 206 according to an embodiment. Unless otherwise noted, components of FIG. 11 may be the same as or generally similar to like components disclosed herein. In some embodiments, the raised frame region 260A can be relatively shorter than the outer region 270A as compared to the BAW resonator 205 of FIG. 10. FIG. 11 shows that the bottom electrode 225 has a tapered end and that the boundary between the raised frame region 260A and the outer region 270A lies over the very end of the taper (i.e., where the bottom electrode 225 terminates).

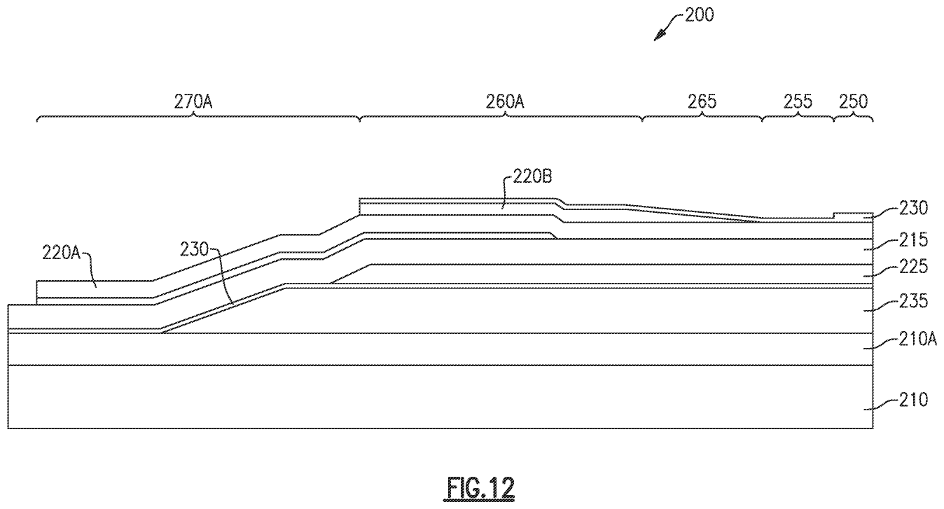

FIG. 12 is a schematic cross sectional side view of a portion of a BAW resonator 206 according to an embodiment. Unless otherwise noted, components of FIG. 11 may be the same as or generally similar to like components disclosed herein. In some embodiments, the raised frame region 260A can be relatively shorter than the outer region 270A as compared to the BAW resonators 205, 206 of FIGS. 10 and 11. FIG. 12 shows that the bottom electrode 225 has a tapered end and that the boundary between the raised frame region 260A and the outer region 270A lies over the beginning of the taper (i.e., at the point where the thickness of the bottom electrode 225 begins to decrease).

In each of FIGS. 10-12, the boundary between the raised frame region 260A and the outer region 270A was shown to be vertical or substantially vertical (i.e. perpendicular to the substrate 210). However, it will be appreciated that other shapes may be used for the boundary, and that the boundary may not be vertical but may instead be at an incline, and may or may not have a constant gradient. In some embodiments, the raised frame of the top electrode 220 can have a tapered shape at the boundary between the raised frame region 260A and the outer region 270A.

It should be appreciated that the BAW resonator illustrated in FIGS. 1 and 7 and 9-12 and other structures illustrated in the figures accompanying this disclosure are illustrated in a simplified form. The relative dimensions of the different features are not shown to scale. Further, embodiments of BAW resonators may include additional features or layers not illustrated or may lack one or more features or layers illustrated herein. Various principles and advantages disclosed herein can be combined in any suitable manner.

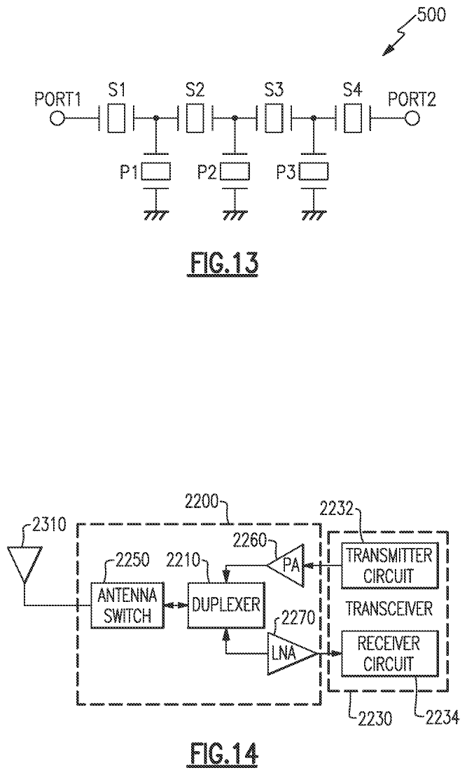

FIG. 13 is a filter 500 according to aspects of the present invention. The filter 500 comprises a plurality of BAW resonators, such as those of FIGS. 1 and 7 and 9-12. The filter 500 is a passband or ladder filter, though it will be appreciated that the BAW resonators described herein can be included in other types of filter.

The ladder filter 500 includes a plurality of series resonators S1, S2, S3, and S4 coupled in series between an input port, PORT1, and an output port, PORT2. The filter 500 also includes a plurality of parallel resonators P1, P2, and P3 connected between terminals of the series resonators and ground. Whilst four series resonators S1, S2, S3, S4 and three parallel resonators P1, P2, P3 are shown, it will be appreciated that more or fewer series and/or parallel resonators may be used.

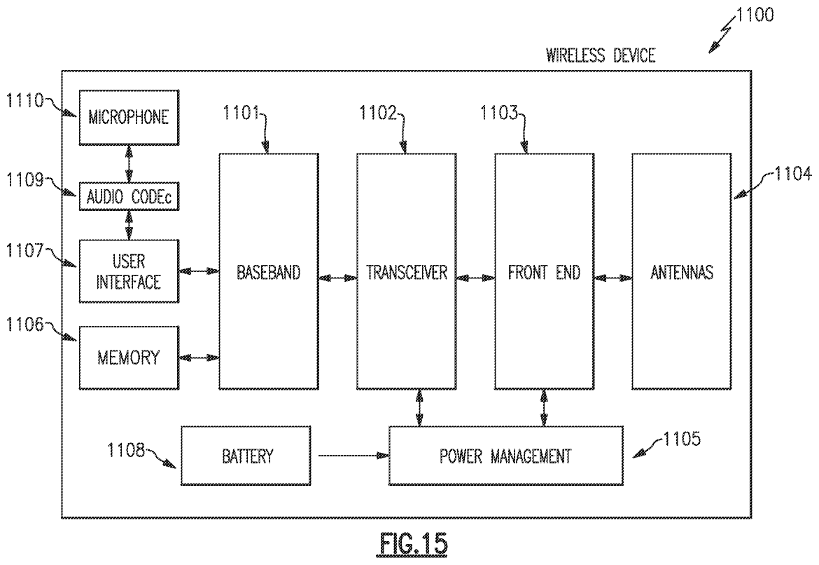

The filter 500 of FIG. 13, or the BAW resonators illustrated in FIGS. 1 and 7 and 9-12, may also be included in a radio-frequency front end (RFFE) module. An exemplary RFFE module is shown in FIG. 14. This figure illustrates a front end module 2200, connected between an antenna 2310 and a transceiver 2230. The front end module 2200 includes a duplexer 2210 in communication with an antenna switch 2250, which itself is in communication with the antenna 2310.

As illustrated, the transceiver 2230 comprises a transmitter circuit 2232. Signals generated for transmission by the transmitter circuit 2232 are received by a power amplifier (PA) module 2260 within the front end module 2200 which amplifies the generated signals from the transceiver 2230. The PA module 2260 can include one or more Pas. The PA module 2260 can be used to amplify a wide variety of RF or other frequency-band transmission signals. For example, the PA module 2260 can receive an enable signal that can be used to pulse the output of the PE to aid in transmitting a wireless local area network (WLAN) signal or any other suitable pulsed signal. The PA module 2260 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the PA module 2260 and associated components including switches and the like can be fabricated on gallium arsenide (GaAs) substrates using, for example, high electron mobility transistors (pHEMT) or insulated-gate bipolar transistors (BiFET), or on a silicon substrate using complementary metal-oxide semiconductor (CMOS) field effect transistors (FETs).

Still referring to FIG. 14, the front end module 2200 may further include a low noise amplifier (LNA) module 2270, which amplifies received signals from the antenna 2310 and provides the amplified signals to the receiver circuit 2234 of the transceiver 2230.

FIG. 15 is a schematic diagram of a wireless device 1100 that can incorporate aspects of the invention. The wireless device 1100 can be, for example but not limited to, a portable telecommunication device such as, a mobile cellular-type telephone. The wireless device 1100 can include a microphone arrangement 1110, and may include one or more of a baseband system 1101, a transceiver 1102, a front end system 1103 (such as the front end module 2200 of FIG. 14), one or more antennas 1104, a power management system 1105, a memory 1106, a user interface 1107, a battery 1108, and audio codec 1109. The microphone arrangement may supply signals to the audio codec 109 which may encode analog audio as digital signals or decode digital signals to analog. The audio codec 1109 may transmit the signals to a user interface 1107. The user interface 1107 transmits signals to the baseband system 1101. The transceiver 1102 generates RF signals for transmission and processes incoming RF signals received from the antennas. The front end system 1103 aids in conditioning signals transmitted to and/or received from the antennas 1104. The antennas 1104 can include antennas used for a wide variety of types of communications. For example, the antennas 1104 can include antennas 1104 for transmitting and/or receiving signals associated with a wide variety of frequencies and communications standards. The baseband system 1101 is coupled to the user interface to facilitate processing of various user input and output, such as voice and data. The baseband system 1101 provides the transceiver 1102 with digital representations of transmit signals, which the transceiver 1102 processes to generate RF signals for transmission. The baseband system 1101 also processes digital representations of received signals provided by the transceiver 1102.

As shown in FIG. 15, the baseband system 1101 is coupled to the memory 1106 to facilitate operation of the wireless device 1100. The memory 1106 can be used for a wide variety of purposes, such as storing data and/or instructions to facilitate the operation of the wireless device 1100 and/or to provide storage of user information. The power management system 1105 provides a number of power management functions of the wireless device 1100. The power management system 1105 receives a battery voltage from the battery 1108. The battery 1108 can be any suitable battery for use in the wireless device, including, for example, a lithium-ion battery.

The BAW resonators described herein, such as those described with respect to FIGS. 7 and 9-12, may be incorporated onto one or more dies used within the wireless device 1100. In particular, a die incorporating BAW resonators according to the present disclosure may be incorporated into a radio-frequency module (e.g., a front end system 1103 such as radio-frequency front end module) which may be incorporated into the wireless device 1100. The BAW resonators may be incorporated into a number of different components which may be incorporated into the wireless device 1100, including but not limited to various forms of filters and duplexers.

The piezoelectric layers of the acoustic devices described herein may have been described with respect to a specific example, though it will be appreciated that other compositions of piezoelectric layer may be used. The required piezoelectric material will be based upon, amongst other considerations, the desired frequency range of operation of the acoustic device. A non-exhaustive list of possible piezoelectric materials includes aluminium nitride (AlN), doped aluminium nitride, lithium niobate (LiNbO₃), lithium tantalate (LiTaO₃), lead titanate (PbTiO₃), and zirconium titanate (ZrTiO₃).

Similarly, a variety of materials may be used for the top and bottom electrodes in each of the embodiments described herein. Preferably, the top and bottom electrodes are formed from a material having a high acoustic impedance. The top and bottom electrodes may be formed from the same material. Suitable materials include, but are not limited to, tungsten (W), platinum (Pt), iridium (Ir), ruthenium (Ru), aluminium (Al), copper (Cu), palladium (Pd), osmium (Os), beryllium (Be), and molybdenum (Mo).

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

Aspects of this disclosure can be implemented in various electronic devices. Examples of the electronic devices can include, but are not limited to, consumer electronic products, parts of the consumer electronic products such as die and/or acoustic wave filter assemblies and/or packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a washer, a dryer, a washer/dryer, a peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave resonator having a central region, an outer region, and a raised frame region between the central region and the outer region, the bulk acoustic wave resonator comprising:
a piezoelectric layer; and
a top electrode over the piezoelectric layer, the top electrode disposed at least in the central region, the outer region, and the raised frame region, the top electrode configured such that a resonant frequency in the outer region is higher than a resonant frequency in the central region.

2. The bulk acoustic wave resonator of claim 1 wherein an resonant frequency in the raised frame region is lower than the resonant frequencies in the central region and the outer region.

3. The bulk acoustic wave resonator of claim 2 wherein a thickness of the top electrode in the raised frame region is greater than a thickness of the top electrode in the central region and a thickness of the top electrode in the outer region.

4. The bulk acoustic wave resonator of claim 3 wherein the top electrode in the raised frame region includes a first layer and a second layer.

5. The bulk acoustic wave resonator of claim 4 wherein materials of the first layer and the second layer are selected from molybdenum (Mo), tungsten (W), platinum (Pt), ruthenium (Ru), iridium (Ir), or osmium (Os).

6. The bulk acoustic wave resonator of claim 1 further comprising a bottom electrode disposed such that the piezoelectric layer is positioned between the top electrode and the bottom electrode, wherein an end of the bottom electrode where the bottom electrode terminates is positioned in the raised frame region or the outer region.

7. The bulk acoustic wave resonator of claim 6 wherein the end of the bottom electrode is positioned within 1 μm from an intersection between the raised frame region and the outer region.

8. The bulk acoustic wave resonator of claim 7 is a mesa type bulk acoustic wave resonator and further comprising:
a substrate; and
an air cavity disposed between the substrate and the bottom electrode.

9. A bulk acoustic wave resonator having a central region, a first outer region, a second outer region, a first raised frame region between the central region and the first outer region, and a second raised frame region between the central region and the second outer region, the bulk acoustic wave resonator comprising:
a top electrode having a first portion and a second portion having a different material from the first portion;
a bottom electrode; and
a piezoelectric layer between the first electrode and the second electrode, an resonant frequency in the first and second outer regions being higher than an resonant frequency in the central region.

10. The bulk acoustic wave resonator of claim 9 wherein an resonant frequency in the first raised frame region and an resonant frequency in the second raised frame region are lower than the resonant frequencies in the central region and the first and second outer regions.

11. The bulk acoustic wave resonator of claim 10 wherein a thickness of the top electrode in the first raised frame region is greater than a thickness of the top electrode in the central region and a thickness of the top electrode in the first outer region.

12. The bulk acoustic wave resonator of claim 11 wherein the top electrode in the raised frame region includes a first layer and a second layer.

13. The bulk acoustic wave resonator of claim 12 wherein materials of the first layer and the second layer are selected from molybdenum (Mo), tungsten (W), platinum (Pt), ruthenium (Ru), iridium (Ir), or osmium (Os).

14. The bulk acoustic wave resonator of claim 10 wherein the resonant frequency in the first raised frame region and the resonant frequency in the second raised frame region are substantially the same.

15. The bulk acoustic wave resonator of claim 10 wherein the resonant frequency in the first outer region and the resonant frequency in the second outer region are substantially the same.

16. The bulk acoustic wave resonator of claim 9 wherein the top electrode extends from the first outer region through the first raised frame region, the central region, and the second raised frame region, and terminates with an intersection between the second raised frame region and the second outer region.

17. The bulk acoustic wave resonator of claim 16 wherein the bottom electrode extends from the second outer region through the second raised frame region and the central region, and an end of the bottom electrode where the bottom electrode terminates is positioned in the first raised frame region or the first outer region.

18. The bulk acoustic wave resonator of claim 17 wherein the end of the bottom electrode is positioned within 1 μm from an intersection between the raised frame region and the outer region.

19. The bulk acoustic wave resonator of claim 18 is a mesa type bulk acoustic wave resonator and further comprising:
a substrate; and
an air cavity disposed between the substrate and the bottom electrode.

20. The bulk acoustic wave resonator of claim 19 further comprising a dielectric layer disposed over the top electrode, wherein the dielectric layer being thicker in the central region than in a recessed frame region between the central region and the first raised frame region.
